(19) United States
(12) Patent Application Publication
(10) Pub. No.: US 2009/0078454 A1
(43) Pub. Date: Mar. 26, 2009

(54) Electronic circuit connecting structure of flat display panel substrate

(75) Inventors: Jin Chen, Suzhou Industrial Park (CN); Hui Li, Suzhou Industrial Park (CN); Rong He, Suzhou Industrial Park (CN)

Correspondence Address: RABIN & Berdo, PC, 1101 14TH STREET, NW, SUITE 500, WASHINGTON, DC, 20005, US

(73) Assignees: AU Optronics (Suzhou) Corp., Ltd., Suzhou Industrial Park (CN); AU OPTRONICS CORP., Hsin-Chu (TW)

(21) Appl. No.: 12/081,457

(22) Filed: Apr. 16, 2008

(30) Foreign Application Priority Data
Sep. 20, 2007 (CN) 200710153480.5

(51) Int. Cl. H05K 1/09; H01R 12/04; H01R 9/00

(52) U.S. Cl. 174/257; 174/267; 29/842

(57) ABSTRACT

An electronic circuit connecting structure of a flat display panel substrate is described. The electronic circuit connecting structure includes a plurality of conductive terminals on the flat display panel substrate and a plurality of conductive protrusions formed on the conductive terminals. In addition, an electronic circuit connecting method for the flat display panel substrate is also disclosed therein.

### RELATED APPLICATIONS

This application claims priority to China Patent Application Serial Number 200710153480.5, filed Sep. 20, 2007, which is herein incorporated by reference in its entirety.

### FIELD OF THE INVENTION

The present invention generally relates to an electronic circuit connecting structure and method. More particularly, this invention relates to an electronic circuit connecting structure and method for a flat display panel substrate.

### BACKGROUND OF THE INVENTION

Electronic products are gradually becoming smaller and lighter. The electronics packaging technology is therefore rapidly developing to satisfy various manufacturing requirements of the newer and smaller electronic products. The packaging technologies for manufacturing the liquid crystal display (LCD) at least include, for example, tape automated bonding (TAB), chip on glass (COG) or chip on film (COF).

In the process to bond the chip to the glass substrate, the flip chip packaging process is adopted to bond the chip having the bumps to the glass substrate using the anisotropic conductive film (ACF) as an intermediate interface there between. In addition, the conductive terminals of the liquid crystal display and the flexible printed circuit board can also be electrically and physically connected together by the ACF.

However, ACF bonding technology uses conductive particles therein to electrically connect the chip and the liquid crystal display substrate. Therefore, some of the ACF connections are poor in the electrical performance so as to easily produce the defect products and increase the manufacture cost of the liquid crystal display. Furthermore, the price of the ACF is expensive and the ACF is difficult to preserve so as to further increase the manufacture cost of the liquid crystal display.

### SUMMARY OF THE INVENTION

One aspect of the present invention is directed to an electronic circuit connecting structure and method for a flat display panel substrate to form conductive protrusions on a conductive terminal for penetrating an adhesive layer and electrically connecting another conductive terminal.

To achieve these and other advantages and in accordance with the objective of the present invention, as the embodiment broadly describes herein, the present invention provides a flat display panel substrate having a plurality of conductive terminals and a plurality of conductive protrusions formed on the conductive terminals.

Both the conductive terminals and the conductive protrusions are preferably made of indium tin oxide (ITO). Preferably, the conductive protrusions and the conductive terminals are formed simultaneously. The conductive protrusions are about three micrometers high and the conductive protrusions are preferably squares, circles, half spheres, cones or polygonal cones.

Another aspect of the present invention is directed to a connecting method for connecting a driving circuit module to a substrate having a plurality of first conductive terminals with a plurality of conductive protrusions thereon. The driving circuit module has a plurality of corresponding second conductive terminals. The driving circuit module is electrically connected to the substrate through the conductive protrusions at a predetermined temperature under a predetermined pressure.

Hence, the connecting structure and the connecting method of the flat display panel substrate can effectively electrically connect the flat display panel substrate to the driving circuit module through the conductive protrusions. Since the conductive protrusions can effectively replace the conductive particles of the ACF, the manufacturing cost of the liquid crystal display can be effectively reduced and the manufacturing quality of the liquid crystal display can be improved.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 illustrates a preferred embodiment of a conductive terminal with conductive protrusions according to the present invention; and

FIG. 2 schematically illustrates a connecting structure of a driving circuit board and a substrate having a conductive terminal with conductive protrusions according to the present invention.

### DETAILED DESCRIPTION OF THE PREFERRED EMBODIMENT

The following description is of the best presently contemplated mode of carrying out the present invention. This description is not to be taken in a limiting sense but is made merely for the purpose of describing the general principles of the invention. The scope of the invention should be determined by referencing the appended claims.

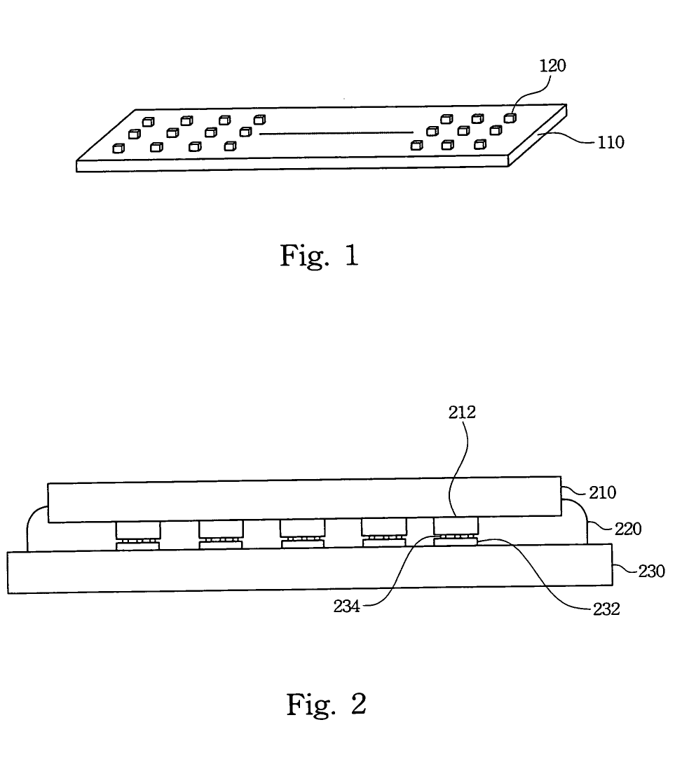

FIG. 1 illustrates a preferred embodiment of a conductive terminal with a plurality of conductive protrusions. The conductive protrusions 120 are formed on the conductive terminal 110. Simultaneously refer to FIG. 2. FIG. 2 schematically illustrates a connecting structure of a driving circuit board and a substrate having a conductive terminal with conductive protrusions thereon. The conductive protrusions 234 are preferably formed on a first terminal 232 of the substrate 230. A second terminal 212 of a driving circuit module 210 is first aligned to the first terminal 232 of the substrate 230 and then adhered to the first terminal 232 of the substrate 230 with an adhesive glue 220. Because a plurality of conductive protrusions 234 are formed on the first terminal 232, the second terminal 212 of the driving circuit module 210 and the first terminal 232 of the substrate 230 can effectively electrically connected after a predetermined pressure and a predetermined temperature is acted thereon. The predetermined pressure and the predetermined temperature can effectively accelerate the conductive protrusions 212 penetrating the adhesive glue 220 to electrically connect to the second terminal 212 and can effectively solidify the adhesive glue 220 to improve the connecting stability of the substrate 230 and the driving circuit module 210.

The first terminal 232 can be a conductive terminal made of metal. Alternatively, the first terminal 232 can be a conductive terminal made of indium tin oxide (ITO). In addition, the conductive protrusions 234 can be conductive protrusions made of metal or ITO. In addition, the conductive protrusions 234 are preferably formed together with the first terminal 232 on the substrate 230. The height of the conductive protrusions 234 are preferably about three micrometers (3 um) and the shape thereof is a square, a circle, a half sphere, a cone, a triangular cone or a polygonal cone.

Therefore, the electronic circuit connecting structure and method of the flat display panel substrate according to the present invention can electrically connect the conductive terminal on the substrate to the conductive terminal on the flexible printed circuit board through the conductive protrusions formed thereon without the expensive anisotropic conductive film so as to effectively reduce the manufacture cost of the liquid crystal display and improve the manufacture quality of the liquid crystal display.

As is understood by a person skilled in the art, the foregoing preferred embodiments of the present invention are illustrative of the present invention rather than limiting of the present invention. It is intended that various modifications and similar arrangements be included within the spirit and scope of the appended claims, the scope of which should be accorded the broadest interpretation so as to encompass all such modifications and similar structures.

What is claimed is:

1. An electronic circuit connecting structure for use in a flat display panel substrate, comprising:
a plurality of conductive terminals disposed on the substrate; and
a plurality of conductive protrusions formed on the conductive terminals.

2. The electronic circuit connecting structure of claim 1, wherein the conductive terminals are made of indium tin oxide.

3. The electronic circuit connecting structure of claim 1, wherein the conductive protrusions are made of indium tin oxide.

4. The electronic circuit connecting structure of claim 1, wherein the conductive protrusions are about 3 micrometer high.

5. The electronic circuit connecting structure of claim 1, wherein the conductive protrusions are square-shaped, circle-shaped, half-sphere-shaped, cone-shaped or polygonal-cone-shaped.

6. A method for connecting a driving circuit module to a substrate having a plurality of first conductive terminals with a plurality of conductive protrusions formed thereon, the driving circuit module having a plurality of corresponding second conductive terminals, the method comprising:
applying an adhesive glue on the first conductive terminals;
aligning the second conductive terminals to the first conductive terminals; and
electrically connecting the driving circuit module to the substrate through the conductive protrusions at a predetermined temperature under a predetermined pressure.

7. The method of claim 6, wherein the conductive protrusions and the conductive terminals are simultaneously formed on the substrate.

8. The method of claim 6, wherein the conductive protrusions are made of indium tin oxide.

9. The method of claim 6, wherein the conductive protrusions are square-shaped, circle-shaped, half-sphere-shaped, cone-shaped, or polygonal-cone-shaped.
